(19) United States
(12) Patent Application Publication
(10) Pub. No.: US 2021/0223029 A1
(43) Pub. Date: Jul. 22, 2021

(54) MEASURING DEVICE, MEASURING SYSTEM, AND MEASURING METHOD

(71) Applicant: MITSUBISHI HEAVY INDUSTRIES, LTD., Tokyo (JP)

(72) Inventor: Hideki TONAKA, Tokyo (JP)

(21) Appl. No.: 17/110,564

(22) Filed: Dec. 3, 2020

(30) Foreign Application Priority Data
Jan. 17, 2020 (JP) 2020-006201

(51) Int. Cl. G01B 11/16; H01L 31/02

(52) U.S. Cl. CPC G01B 11/16; H01L 31/02021

(57) ABSTRACT

A measuring device provided is a measuring device that is connected to at least one sensor, and includes a power source unit connected to an outside power source as a power supplying source and configured to be supplied with input power, from the outside power source, in which a modulation power signal is superimposed on power-source power for the measuring device, and also includes a controller configured to control the presence or absence of supply of power to the at least one sensor based on the modulation power signal.

### CROSS-REFERENCE TO RELATED APPLICATIONS

This application claims the benefit of priority to Japanese Patent Application Number 2020-006201 filed on Jan. 17, 2020. The entire contents of the above-identified application are hereby incorporated by reference.

### TECHNICAL FIELD

The disclosure relates to a measuring device, a measuring system, and a measuring method configured to perform measurement by a plurality of sensors installed on a subject to be measured.

### RELATED ART

Telemeter technology is known in which, for example, detection signals of sensors indicating strains, vibrations, temperatures, and the like obtained from a plurality of sensors installed on a subject to be measured, such as strains and rotational torque at the rotation time of a rotor blade of a turbine, and vibrations and temperatures of piping, a vehicle (a railway vehicle, automobile, or the like), and industrial machinery, are transmitted by wireless to a location remote from the subject to be measured (JP 8-210929 A, JP 2002-5646 A, and JP 2005-141439 A).

For example, in JP 8-210929 A, it is disclosed that a plurality of strain gauges attached to a rotating body such as a rotor blade of a turbine, a multiplexer configured to receive pieces of detection data from each of the strain gauges and select and output one of them, a telemeter transmitter configured to transmit the detection data outputted from the multiplexer as wireless information to a stationary side, a reception controller configured to receive a sensor selection signal transmitted as wireless information from the stationary side, and a switching controller configured to control switching operation of the multiplexer to select detection data of one strain gauge from among the plurality of strain gauges in response to the received sensor selection signal are installed on the rotating body side, while a transmission controller configured to transmit, as wireless information, a sensor selection signal which is a command to select one strain gauge from among the plurality of strain gauges, and the like are installed on the stationary side.

JP 2002-5646 A discloses that a trigger signal is sequentially transmitted by wireless through manual operation to a plurality of linear gauges (displacement sensors) in which a battery is used as a power source, whereby the measurement of a site to be measured is started and a measurement signal by the linear gauge is digitally converted and sent as a reply. Further, in JP 2005-141439 A, it is disclosed that a sensor includes a self-generating module configured to perform photovoltaic generation by a solar battery, or the like.

### SUMMARY

For example, as in JP 8-210929 A and JP 2002-5646 A, in order to process, on the rotating body side, control commands such as a sensor selection signal transmitted from the stationary side, a function unit (such as a reception circuit) for receiving and processing the control commands transmitted by wireless communication to a device such as a telemeter (hereinafter, referred to as a measuring device) installed on the rotating body side is needed. This leads to a larger measuring device and an increased power consumption.

In addition, when a sensor itself includes a self-generating module such as a solar battery as in JP 2005-141439 A, the sensor increases in size. As such, it is conceivable to supply power to each of a plurality of sensors from a measuring instrument connected to the plurality of sensors. However, in a case where the power is supplied from the measuring device to all of the plurality of sensors, the measuring device itself may be increased in size, and a technique for supplying such large power to the measuring instrument is also required additionally.

In light of the above-described circumstances, an object of at least one embodiment of the disclosure is to provide a measuring device able to process control commands transmitted from a remote side while reducing power consumption.

A measuring device according to at least one embodiment of the disclosure is a measuring device connected to at least one sensor, the measuring device including: a power source unit connected to an outside power source as a power supplying source and configured to be supplied with input power, from the outside power source, in which a modulation power signal is superimposed on power-source power for the measuring device; and a controller configured to control the presence or absence of supply of power to the at least one sensor based on the modulation power signal.

A measuring system according to at least one embodiment of the disclosure includes: the above-described measuring device; at least one sensor connected to the measuring device; and an outside power source that is a power supplying source of power-source power needed for operation of the measuring device, and is able to supply input power, in which a modulation power signal is superimposed on the power-source power, to the measuring device.

A measuring method according to at least one embodiment of the disclosure is a measuring method for performing measurement by at least one sensor, the method including: a step of acquiring input power in which a modulation power signal is superimposed on power-source power, from an outside power source as a power supplying source; and a step of controlling the presence or absence of supply of power to the at least one sensor based on the modulation power signal.

According to at least one embodiment of the disclosure, there is provided a measuring device able to process control commands transmitted from a remote side while reducing power consumption.

### BRIEF DESCRIPTION OF DRAWINGS

The disclosure will be described with reference to the accompanying drawings, wherein like numbers reference like elements.

FIG. 1 is a diagram schematically illustrating a configuration of a measuring system according to one embodiment of the disclosure.

FIG. 2 is a diagram schematically illustrating a configuration of a measuring device according to one embodiment of the disclosure.

FIG. 3 is a diagram for describing a modulation power signal according to one embodiment of the disclosure.

FIG. 4 is a diagram schematically illustrating a configuration of a measuring device according to another embodiment of the disclosure.

FIG. 5 is a diagram schematically illustrating a configuration of a measuring device according to another embodiment of the disclosure.

FIG. 6 is a diagram schematically illustrating a configuration of an outside power source according to one embodiment of the disclosure, where the outside power source is a wireless power supply device of a photoelectric conversion scheme.

FIG. 7 is a diagram schematically illustrating a configuration of an outside power source according to one embodiment of the disclosure, where the outside power source is a wireless power supply device of an electromagnetic induction scheme.

FIG. 8 is a diagram schematically illustrating a configuration of an outside power source according to one embodiment of the disclosure, where the outside power source is a wireless power supply device of an electromagnetic wave scheme.

FIG. 9 is a diagram illustrating a measuring method according to one embodiment of the disclosure.

### DESCRIPTION OF EMBODIMENTS

Embodiments of the disclosure will be described hereinafter with reference to the appended drawings. It is intended, however, that unless particularly specified, dimensions, materials, shapes, relative positions and the like of components described in the embodiments shall be interpreted as illustrative only and not intended to limit the scope of the disclosure.

For instance, an expression of relative or absolute arrangement such as “in a direction”, “along a direction”, “parallel”, “orthogonal”, “centered”, “concentric” and “coaxial” shall not be construed as indicating only the arrangement in a strict literal sense, but also includes a state where the arrangement is relatively displaced by a tolerance, or by an angle or a distance whereby it is possible to achieve the same function.

For instance, an expression of an equal state such as “same”, “equal” and “uniform” shall not be construed as indicating only the state in which the feature is strictly equal, but also includes a state in which there is a slight tolerance or difference with which the same function can still be achieved.

Further, for instance, an expression of a shape such as a rectangular shape or a cylindrical shape shall not be construed as only the geometrically strict shape, but also includes a shape with unevenness or chamfered corners within the range in which the same effect can be achieved.

On the other hand, an expression such as “comprise”, “include”, “have”, “contain” and “constitute” are not intended to be exclusive of other components.

Configuration of Measuring System 6

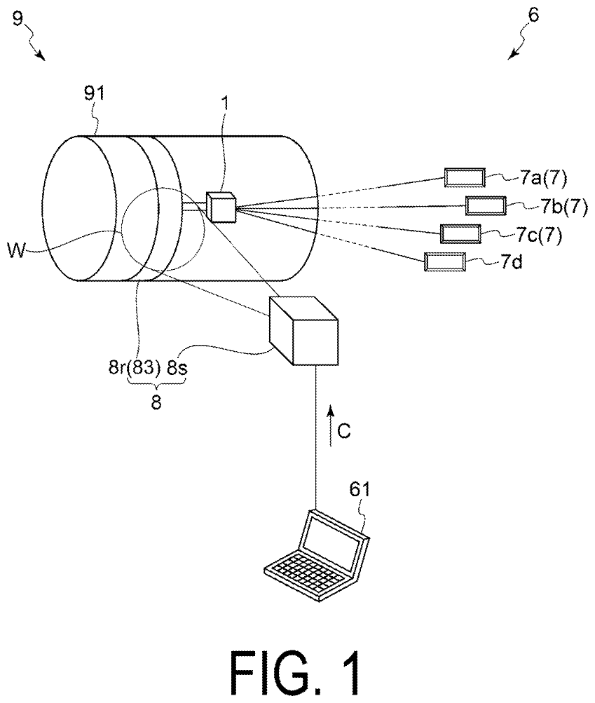

FIG. 1 is a diagram schematically illustrating a configuration of a measuring system 6 according to one embodiment of the disclosure.

As illustrated in FIG. 1, a measuring system 6 includes: at least one sensor 7 installed on a subject to be measured 9 or in the vicinity (periphery) thereof in order to perform measurement regarding the subject to be measured 9; a measuring device 1 connected to the at least one sensor 7; and an outside power source 8, which is a power supplying source able to supply power-source power Pa needed for operation of the measuring device 1 and is able to supply input power P, in which a modulation power signal S is superimposed on the power-source power Pa, to the measuring device 1. In other words, the measuring device 1 is so configured as to be able to perform measurement by using the power-source power Pa from the outside power source 8. Furthermore, as described below, the measuring device 1 is so configured as to be able to perform control in response to a control command C, which is predetermined in accordance with the above-described modulation power signal S.

More specifically, the subject to be measured 9 refers to, for example, a rotating body of a turbine or the like, piping, a vehicle (for example, a railway vehicle, automobile, or the like), or industrial machinery. The sensor 7 is, for example, an instrument able to detect physical quantities such as strain, torque, vibration, temperature and pressure, and is, for example, a strain gauge (strain sensor), a vibration sensor, a temperature sensor, or a pressure sensor. When a plurality of the sensors 7 are connected to the measuring device 1, the plurality of sensors 7 may be such sensors that mutually detect physical quantities of the same type, or may be such sensors that include at least one sensor configured to detect a different type of physical quantity from the others.

As illustrated in FIG. 1, an operation terminal 61 (computer) such as a laptop PC or a tablet is connected to the outside power source 8, for example, and with this configuration, the control command C (to be explained later) may be executed by the measuring device 1 by controlling the outside power source 8. The outside power source 8 may be a power supply device connected to a power supplying source (not illustrated) by wire, or a wireless power supply device as described below. The wireless power supply device includes a power transmitter 8s configured to transmit power and a power receiver 8r configured to receive the power transmitted by wireless.

The subject to be measured 9 of the embodiment illustrated in FIG. 1 is a turbine. The measuring device 1 is installed on a rotary shaft 91 of the turbine, and a plurality of (four in FIG. 1) strain gauges (sensors 7) are connected thereto. All of the sensors 7 are installed on rotor blades (rotary blades) (not illustrated) of the turbine, and the measuring device 1 measures the amount of strain generated in the rotor blades when the turbine is in operation. On the other hand, the outside power source 8 is a wireless power supply device of an optical wireless power supply scheme configured to supply the power-source power Pa to the measuring device 1, and communicate the control command C to the measuring device 1 by supplying power to the measuring device 1 in a state in which the modulation power signal S, corresponding to the control command C and received from the operation terminal 61, is superimposed on the power-source power Pa.

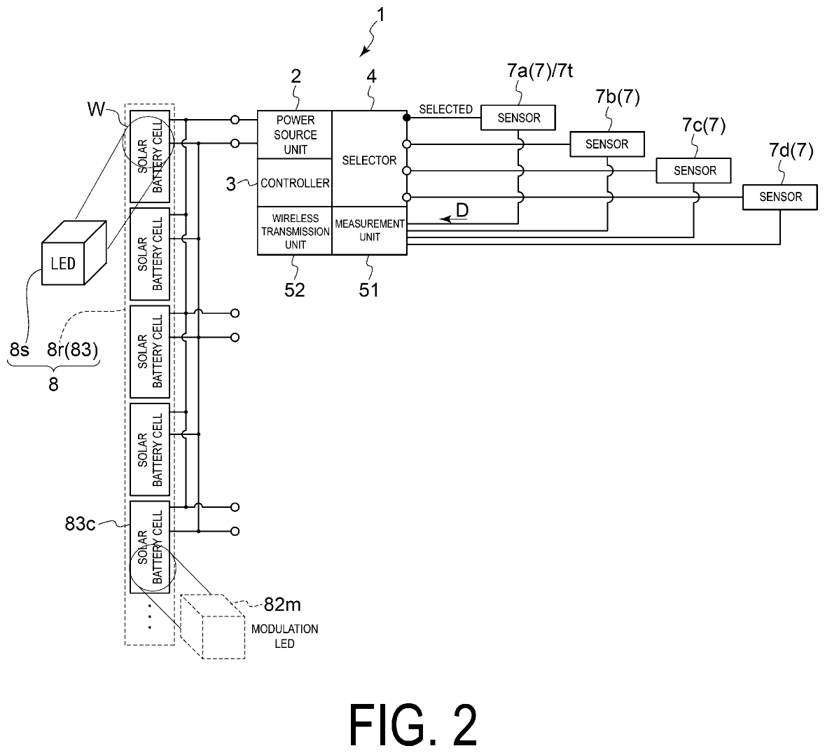

Next, the measuring device 1 will be described in detail using FIGS. 2 to 5.

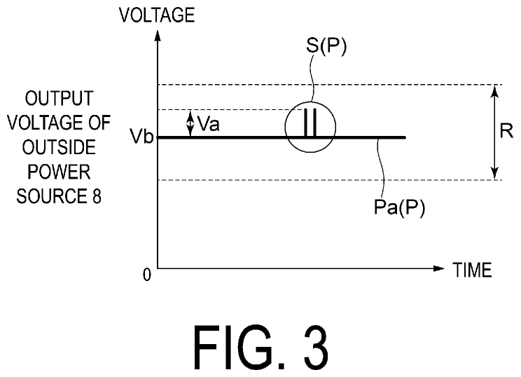

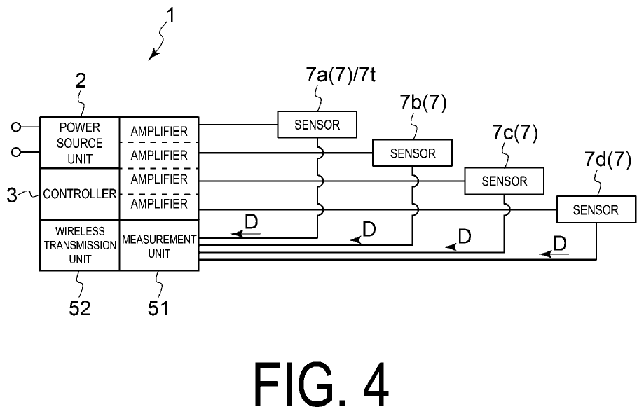

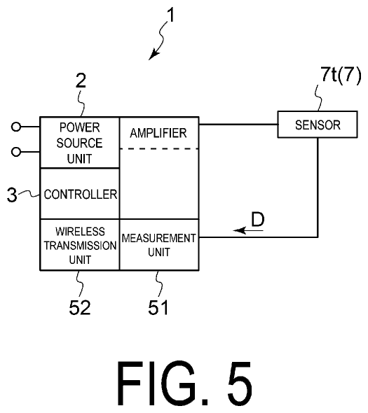

FIG. 2 is a diagram schematically illustrating a configuration of the measuring device 1 according to one embodiment of the disclosure, where the measuring device 1 includes a selector 4. FIG. 3 is a diagram for describing the modulation power signal S according to one embodiment of the disclosure. FIG. 4 is a diagram schematically illustrating a configuration of the measuring device 1 according to another embodiment of the disclosure. FIG. 5 is a diagram schematically illustrating a configuration of the measuring device 1 according to another embodiment of the disclosure.

In the embodiment illustrated in FIG. 2, the power-source power Pa supplied from the outside power source 8 to the measuring device 1 is a DC voltage, and this case will be described as an example.

Configuration of Measuring Device 1

As illustrated in FIG. 2 (the same applies to FIGS. 4 and 5, and FIGS. 7 and 8), the measuring device 1 includes: a power source unit 2 connected to the outside power source 8 and configured to be supplied with the input power P (input voltage; the same hereinafter), from the outside power source 8, in which the modulation power signal S is superimposed on the power-source power Pa (DC voltage; the same hereinafter); and a controller 3 configured to control the presence or absence of supply of power to at least one sensor 7 connected to the measuring device 1 based on the modulation power signal S. That is, the power source unit 2 is connected to the outside power source 8, and the measuring device 1 is powered on by being supplied with the input power P at least including the power-source power Pa.

Specifically, the superimposing of the modulation power signal S is performed by modulating the power-source power Pa to be supplied to the measuring device 1 in accordance with the control command C. More specifically, after any control command C is encoded, as illustrated in FIG. 3, the superimposing may be performed by the power-source power Pa to be supplied to the measuring device 1 being modulated in accordance with the encoded information. To be specific, for example, in a case where a code by which the control command C indicates a command to execute supply of power to a fourth sensor 7d is determined as “11”, the input power P with the power-source power Pa having been modulated in accordance with the information of “11” is output from the outside power source 8.

A well-known modulation scheme such as amplitude modulation, frequency modulation, phase modulation, or pulse modulation may be used for the modulation described above. In the example illustrated in FIG. 3, the pulse modulation is used, and when the control command C is not communicated, a DC voltage (power-source power Pa) having a voltage value (Vb in FIG. 3) within an operation voltage range R of the measuring device 1 is output from the outside power source 8. On the other hand, when the control command C is communicated, the modulation power signal S is superimposed by superimposing a pulsed voltage having a positive voltage value (Va in FIG. 3) on the DC voltage. A pulsed voltage having a negative value may be superimposed, and in this case, when the control command C is communicated, the DC voltage is partially smaller than the voltage value Vb by Va.

At this time, the correspondence between the content of the control command C and the modulation power signal S may be made by using a well-known technique. For example, at least one among number of pulses, pulse width, pulse height, and appearance pattern may be made different from that of the others to obtain the above correspondence. As for the number of pulses, for example, it is conceivable that a first sensor 7a takes one pulse, a second sensor 7b takes two pulses, and the like. As for the pulse width, for example, it is conceivable that the first sensor 7a takes one unit time, the second sensor 7b takes two unit times, and the like. As for the appearance pattern of the pulses, for example, it is conceivable that the control command C is encoded by a list of binary values 0 and 1, and the presence or absence of the pulse is arranged in accordance with the list, thereby making the appearance pattern.

Then, the measuring device 1 separates the modulation power signal S from the input power P (Pa+S), or the like to reproduce the information of “11” from the modulation power signal S, and refers to a conversion table in which the code is associated with the control command C, or the like, thereby making it possible to determine the content of the control command C. Specifically, the modulation power signal S separated from the input power P, or the like may be input to the controller 3, or the modulation power signal S separated by a separator (not illustrated) such as a high-pass filter installed between the power source unit 2 and the controller 3 may be input to the controller 3. Alternatively, encoded information reproduced from the modulation power signal S may be input to the controller 3. The controller 3 determines and executes the content of the control command C based on such input.

In the case where the plurality of sensors 7 are connected to the measuring device 1, for example, the content of the control command C may be a selection command to select the sensor 7 (hereinafter, referred to as target sensor 7t) to be supplied with power to actually perform measurement from among the plurality of sensors 7. Alternatively, regardless of the number of sensors 7 connected to the measuring device 1, the content of the control command C may be a stop command to stop the supply of power to the target sensor 7t, a start command to start the supply of power thereto, or the like.

For example, in a case where the supply of power to all of the sensors 7 connected to the measuring device 1 is difficult or ought to be avoided from the perspective of power consumption or the like, it is possible to save the power of the measuring device 1 by limiting the supply of power to some of the sensors 7, for example, one sensor or the like, by the selection command. Further, for example, in a turbine or the like, testing (verification) of the vibration characteristics may be performed by using the sensor 7 (for example, a strain gauge) installed on a rotor blade of the turbine, but the opportunity to perform the testing thereof is limited. At this time, since a centrifugal force acts on the sensor 7 installed on a high-speed rotating body of the turbine or the like, the installed sensor 7 may be damaged during the testing. However, in a case where the sensor 7 is damaged, it is possible to continue the measurement without interruption by switching to another normal sensor 7, thereby making it possible to reliably obtain effective measurement data necessary for the testing (verification) at a precious testing opportunity.

In the embodiment illustrated in FIG. 2, the measuring device 1 further includes the selector 4 connected to each of the plurality of sensors 7 and the power source unit 2. The selector 4 is configured to be able to make the target sensor 7t and the power source unit 2 in a connection status, and also able to make the other sensors 7 excluding the target sensor 7t and the power source unit 2 in a non-connection status. Then, when a selection command is input, the controller 3 controls the selector 4 in such a manner that the target sensor 7t specified based on the selection command and the power source unit 2 are set to be in a connection status. Note that in the measuring device 1, the power source unit 2 and the selector 4 may be connected via an amplifier configured to amplify the power, or the selector 4 and each of the plurality of sensors 7 may be connected via the amplifier.

More specifically, in the embodiment illustrated in FIG. 2, the selector 4 makes one sensor 7 in a connection status among the plurality of sensors 7 and makes the other sensors 7 in a non-connection status. To be specific, by bringing the first sensor 7a selected by the selection command and the power source unit 2 into the connection status, three other sensors including the second sensor 7b, a third sensor 7c, and the fourth sensor 7d are set to be in the non-connection status. Note that the measurement can be performed by the sensor 7 in the connection status, but it is not possible to perform the measurement by the sensor 7 in the non-connection status.

The disclosure is not limited to the embodiment illustrated in FIG. 2. In some other embodiments, as illustrated in FIGS. 4 and 5, the measuring device 1 may not include the selector 4 described above. In an embodiment illustrated in FIG. 4, the measuring device 1 is able to perform measurement using all of the sensors 7 simultaneously by being supplied with power, from the outside power source 8, that is larger than that of the measuring device 1 illustrated in FIG. 2. In a case of a wireless power supply device of an optical wireless power supply scheme as described later, it is possible to increase the amount of light of a light source 82. In an embodiment illustrated in FIG. 5, one sensor 7 is connected to the measuring device 1. In such a case, the controller 3 processes a start command, a stop command, and the like as the control commands C, for example, thereby making it possible to individually control the start, stop, and the like of the measurement of the sensor 7 designated by the commands (the start, stop, and the like of the supply of power).

For example, as illustrated in FIG. 2, in the case where the outside power source 8 is provided with a plurality of terminals for connecting the measuring devices 1, when one or more of these various types of measuring devices 1 are simultaneously installed on the subject to be measured 9 or the like, it is possible to perform the measurement using the sensors 7, the number of which exceeds the maximum number of sensors 7 connectable to one measuring device 1.

Then, the measuring device 1 includes a measurement unit 51 (see FIGS. 2, 4, and 5), and thus acquires a measurement value by being input with a value detected by the sensor 7. In the present embodiment, each of the plurality of sensors 7 is a strain gauge and is configured such that a detection value D obtained by each sensor 7 is able to be input. That is, the measurement unit 51 is able to measure the amount of strain by being input with a voltage change corresponding to a change in an electrical resistance value of the strain gauge caused by the strain when a constant input voltage is applied to the strain gauge from the power source unit 2.

According to the above-described configuration, on the power-source power Pa to be supplied to the measuring device 1 from the outside power source 8 as a power supplying source for the measuring device 1, the modulation power signal S corresponding to the control command C for switching the presence or absence of the supply of power to each of the sensors 7 connected to the measuring device 1 is superimposed, and the power-source power Pa and the modulation power signal S are able to be simultaneously input from the outside power source 8 to the measuring device 1. Then, in the case where the modulation power signal S is contained in the input power P, the measuring device 1 determines the control command C based on the modulation power signal S taken out from the input power P, and performs control such as switching (selecting) of the sensor 7 (target sensor 7t) to be supplied with power, starting or stopping of the supply of power to the target sensor 7t, or the like.

As a result, the control commands C for the activation or stopping of the desired sensor 7, the switching of the sensor 7 used when the plurality of sensors 7 are present, and the like which are carried out from a stationary side or the like remote from the subject to be measured 9, may be received and executed without additionally including a reception circuit and the like needed for wireless communication. Thus, the measuring device 1 can be reduced in power consumption, reduced in size, and the like.

In some embodiments of the embodiments described above, the measuring device 1 may further include a wireless transmission unit 52 configured to wirelessly transmit the detection result obtained by the target sensor 7t, as illustrated in FIGS. 2, 4, and 5. In the embodiments illustrated in FIGS. 2, 4, and 5, the measurement unit 51 calculates a measurement value based on a voltage change detected by the detection value D of the target sensor 7t, and the measurement value (detection result) is transmitted from the wireless transmission unit 52 by wireless communication to a predetermined communication destination. In this case, the wireless communication may be near field communication such as Bluetooth (registered trademark) in addition to Wi-Fi, mobile communication such as 4G or 5G, and the like.

According to the configuration described above, the measuring device 1 is configured to be able to transmit the detection result of the target sensor 7t to the outside by wireless. This makes it possible to easily obtain a measurement value at a remote location. In this case, as described above, the measuring device 1 can receive the control command C by the modulation power signal S, and thus it is possible to omit a reception circuit or the like for wireless communication in the measuring device 1, thereby making it possible to reduce in power consumption and to reduce in size of the measuring device 1 by omitting the reception circuit while including the wireless transmission unit 52 (transmission circuit).

Configuration of Outside Power Source 8

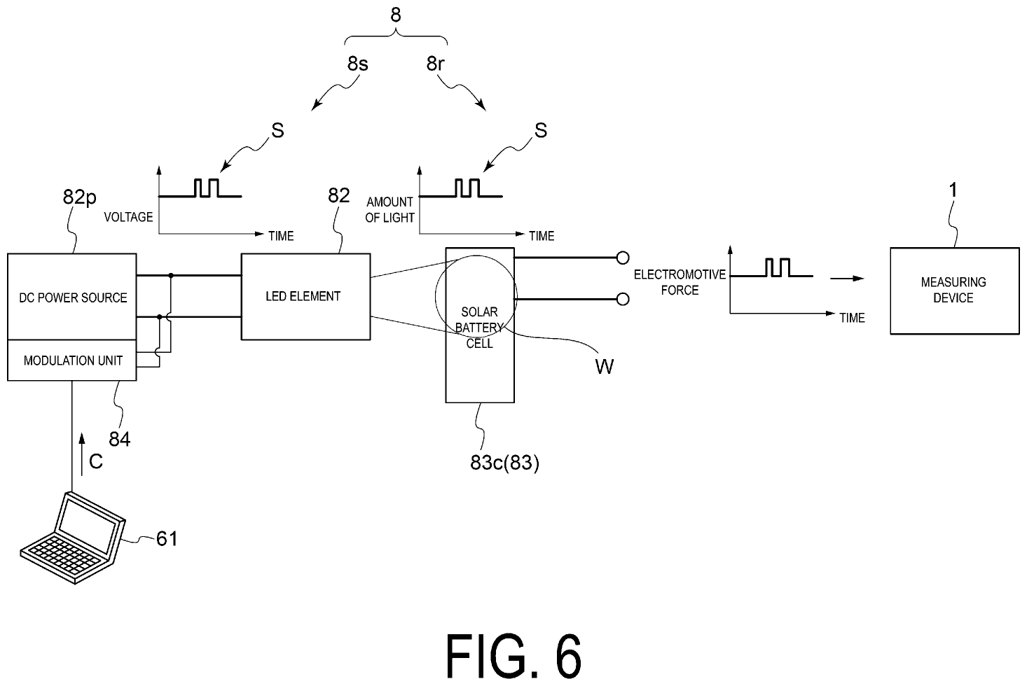

Some embodiments regarding the outside power source 8 will be described below. FIGS. 6 to 8 are diagrams each schematically illustrating a configuration of the outside power source 8 according to one embodiment of the disclosure.

In some embodiments, as illustrated in FIGS. 6 to 8, the outside power source 8 may be a wireless power supply device configured to wirelessly supply the power to the measuring device 1.

Specifically, as illustrated in FIG. 6 (the same applies to FIGS. 1 and 2), the outside power source 8 may be a wireless power supply device of a wireless power supply scheme using light (photoelectric conversion scheme) in some embodiments. That is, the wireless power supply device of the photoelectric conversion scheme includes the light source 82, a solar battery 83 capable of generating an electromotive force in accordance with irradiation light W from the light source 82, and a modulation unit 84 configured to modulate the irradiation light W emitted to the solar battery 83 in accordance with the control command C communicated to the controller 3 of the measuring device 1. The power transmitter 8s is constituted by the light source 82, a DC power source 82p (to be described below) and the modulation unit 84, and the power receiver 8r is constituted by the solar battery 83.

In the embodiment illustrated in FIG. 6, the light source 82 is a light source using an LED element. The DC power source 82p and the modulation unit 84 are respectively connected to the light source 82, and the light source 82 emits light with intensity in accordance with the inputted voltage. The modulation unit 84 includes a modulation circuit, and modulates a voltage supplied from the DC power source 82p to the light source 82 in accordance with the control command C inputted from the operation terminal 61 described above. With this, by changing the input voltage to the light source 82, the modulation power signal S is superimposed on the DC voltage generated by the solar battery 83 by the irradiation light W being emitted. The solar battery 83 is connected to the measuring device 1 (see FIG. 2), and applies, to the measuring device 1, the input voltage (the DC voltage and modulation voltage signal) corresponding to the amount of light of the irradiation light W or the like. As a result, the power-source power Pa on which the above-described modulation power signal S is superimposed is input to the measuring device 1 (the power source unit 2).

In the embodiments illustrated in FIGS. 1 to 6, the solar battery 83 is installed along the circumferential direction on the rotary shaft 91 of the turbine, as illustrated in FIG. 1. Specifically, as illustrated in FIG. 2, the solar battery 83 is constituted of a plurality of solar battery cells 83c, and the plurality of solar battery cells 83c are arranged in series along the circumferential direction of the rotary shaft 91 in such a manner that the power (electromotive force) is supplied from the plurality of solar battery cells 83c in parallel to the measuring device 1.

On the other hand, the light source 82 is installed so as to emit the irradiation light W from one direction toward a position in an axial direction of the rotary shaft 91, on which the solar battery 83 (solar battery cells 83c) in the rotary shaft 91 is installed. This allows the solar battery 83 to generate constant power by any site of the solar battery 83 being irradiated with the irradiation light W even when there is only one light source 82.

In the embodiment illustrated in FIG. 6, the irradiation light W of one light source 82 is modulated, but in some other embodiments, as illustrated in FIG. 2, the light source 82 for generating the power-source power Pa by the solar battery 83, and a modulation light source 82m for generating the modulation power signal S by the solar battery 83 may be provided separately; then, the modulation unit 84 controls the modulation light source 82m to emit the modulated irradiation light W to the solar battery 83, whereby the above-described input power P may be output from the outside power source 8.

According to the configuration described above, the outside power source 8 of the measuring device 1 is a wireless power supply device configured to perform optical wireless power supply, and the control command C for the measuring device 1 is communicated to the measuring device 1 by modulating the irradiation light W emitted from the light source 82 to the solar battery 83 in accordance with the control command C. The electromotive force generated by the solar battery varies depending on the amount of light of the irradiation light W or the like, but the modulation power signal S can be easily superimposed on the electromotive force (DC voltage) for enabling the measuring device 1 to operate by modulating the irradiation light W from the light source 82. Further, in comparison with a case where a battery or the like is built in each of the sensors 7, the measuring device 1, or the like, it is possible to eliminate the need for replacing the battery, thereby making it possible to improve the efficiency of the measurement.

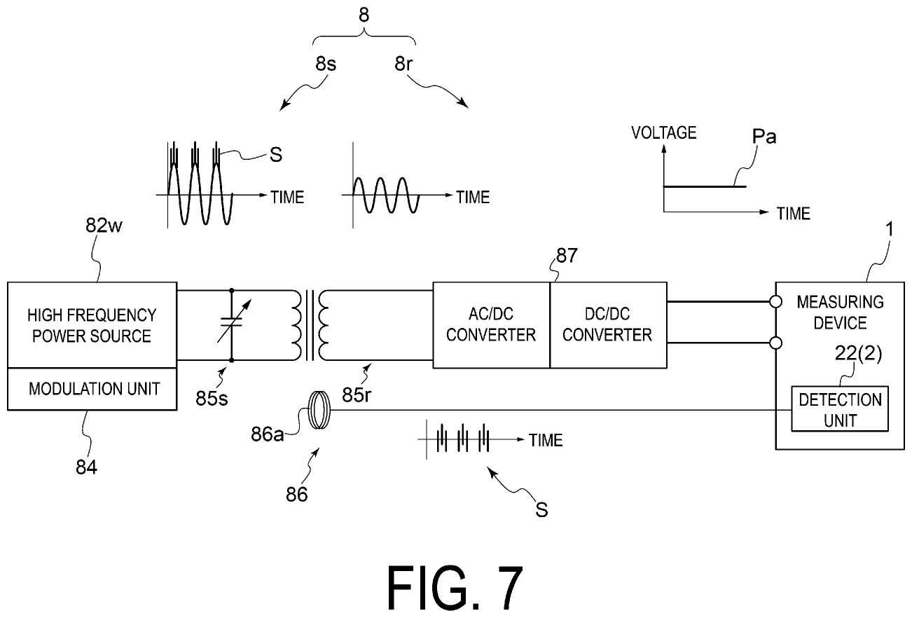

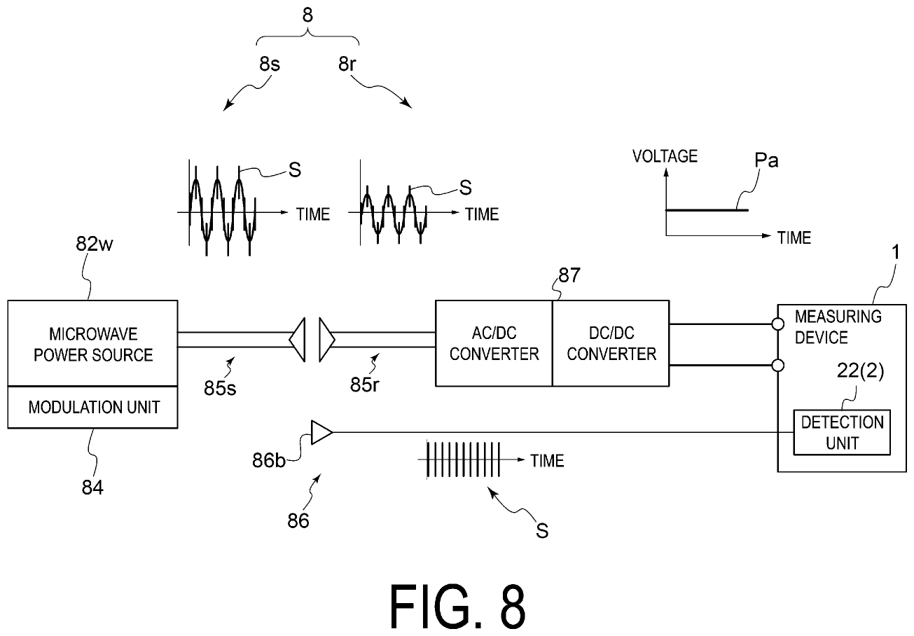

Note that the disclosure is not limited to the embodiment illustrated in FIG. 6. In the case where the outside power source 8 is a wireless power supply device, the outside power source 8 may be of another wireless power supply scheme belonging to a radiation type, a non-radiation type, or the like. For example, in some embodiments, the outside power source 8 may be a wireless power supply device of an electromagnetic induction scheme (non-radiation type), as illustrated in FIG. 7. In some other embodiments, the outside power source 8 may be a wireless power supply device of an electromagnetic wave scheme (radiation type) using microwaves or the like, as illustrated in FIG. 8. Note that the measuring device 1 illustrated in FIGS. 7 and 8 is the same as that having been described before, and the function units included in the measuring device 1 are indicated within a range necessary for giving the description.

That is, in some embodiments, as illustrated in FIGS. 7 and 8, a wireless power supply device as the outside power source 8 includes: an AC power source 82w, a power transmission circuit section 85s configured to wirelessly transmit AC power outputted from the AC power source 82w; a power reception circuit section 85r configured to receive the AC power wirelessly transmitted from the power transmission circuit section 85s; and the modulation unit 84 configured to modulate the AC power to be wirelessly transmitted to the power reception circuit section 85r in accordance with the control command C to be communicated to the measuring device 1 (controller 3). The measuring device 1 includes a separator section 86 configured to separate a modulation component of the AC power transmitted wirelessly from the power transmission circuit section 85s to the power reception circuit section 85r, and the measuring device 1 (controller 3) includes a detection unit 22 configured to detect the modulation power signal S by using the separator section 86. More specifically, the detection unit 22 belongs to the power source unit 2 of the measuring device 1.

In the embodiment illustrated in FIG. 7, the outside power source 8 is a wireless power supply device of an electromagnetic induction scheme, and the AC power source 82w is a high frequency power source. The power transmission circuit section 85s and the power reception circuit section 85r each include a coil opposing each other. The power reception circuit section 85r includes a rectifier section 87 (a combination of an AC/DC converter and a DC/DC converter in FIGS. 7 and 8) configured to convert, to DC, AC components other than a modulation component (modulation power signal S) superimposed on a change in magnetic flux, and supply the converted DC to the measuring device 1 (power source unit 2) as the above-discussed power-source power Pa. The separator section 86 includes a search coil 86a and is configured to input the modulation power signal S to the measuring device 1 (power source unit 2).

On the other hand, in the embodiment illustrated in FIG. 8, the outside power source 8 is a wireless power supply device of an electromagnetic wave scheme, and the AC power source 82w is a microwave power source. The power reception circuit section 85r includes the rectifier section 87 (a combination of the AC/DC converter and the DC/DC converter) configured to convert, to DC, AC components other than a modulation component (modulation power signal S) superimposed on microwaves emitted from the power transmission circuit section 85s, and supply the converted DC to the measuring device 1 (power source unit 2) as the power-source power Pa. The separator section 86 includes a search antenna 86b, and is configured to input the modulation power signal S to the measuring device 1 (power source unit 2).

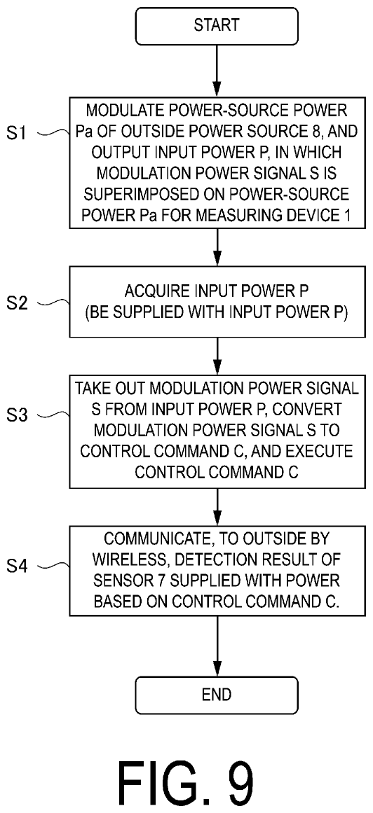

Hereinafter, a measuring method corresponding to a process performed by the measuring device 1 provided with the configuration (functions) described above will be described with reference to FIG. 9. FIG. 9 is a diagram illustrating a measuring method according to one embodiment of the disclosure.

The measuring method illustrated in FIG. 9 is a measuring method for performing measurement using at least one sensor 7 installed on the subject to be measured 9. As illustrated in FIG. 9, the method includes an acquisition step of acquiring input power in which the modulation power signal S is superimposed on the power-source power, from the outside power source 8 as described above, and a control step of controlling the supply of power to at least one sensor 7 based on the modulation power signal S. The acquisition step and the control step are the same as processing contents performed by the power source unit 2 and the controller 3 described above, and thus detailed description thereof will be omitted.

In step S1 of FIG. 9, the power-source power Pa for the measuring device 1 is modulated in accordance with the control command C in the outside power source 8, and the power (input power P) in which the modulation power signal S is superimposed on the power-source power Pa is output toward the measuring device 1. In step S2, the acquisition step described above is performed. Then, the control step is performed in step S3. In other words, the modulation power signal S is taken out from the acquired input power P, the stated modulation power signal S is converted to the control command C, and then the control command C is executed.

Specifically, in step S3, in a case where the control command C is the above-described selection command, power is supplied to the target sensor 7t in such a manner that the power source unit 2 is brought into a connection status with the target sensor 7t specified by the control command C, and power is not supplied to the other sensor 7 excluding the target sensor 7t in such a manner that the above-mentioned other sensors 7 and the power source unit 2 are set to be in a non-connection status. In the case where the control command C is a start command or a stop command, the supply of power to the target sensor 7t is started (stopped) in such a manner that the target sensor 7t specified based on the start or stop command and the power source unit 2 are brought into a connection status or a non-connection status.

In some embodiments, the measuring method described above may further include a wireless transmission step of wirelessly transmitting the detection result obtained by the sensor 7, as illustrated in FIG. 9. In the embodiment illustrated in FIG. 9, the wireless transmission step is performed in step S4. The wireless transmission step is the same as the processing content performed by the wireless transmission unit 52 described above, and thus detailed description thereof will be omitted.

The disclosure is not limited to the embodiments described above, and also includes a modification of the above-described embodiments as well as appropriate combinations of these modes.

Supplement

(1) A measuring device 1 according to at least one embodiment of the disclosure is a measuring device 1 connected to at least one sensor 7, the measuring device 1 including: a power source unit 2 connected to an outside power source 8 as a power supplying source and configured to be supplied with input power P, from the outside power source 8, in which a modulation power signal S is superimposed on power-source power Pa for the measuring device 1; and a controller 3 configured to control the presence or absence of supply of power to the at least one sensor 7 based on the modulation power signal S.

According to the configuration of (1), on the power-source power Pa to be supplied to the measuring device 1 from the outside power source 8 as a power supplying source for the measuring device 1, the modulation power signal S corresponding to a control command C for switching the presence or absence of the supply of power to each of the sensors 7 connected to the measuring device 1 is superimposed, and the power-source power Pa and the modulation power signal S are able to be simultaneously input from the outside power source 8 to the measuring device 1. Then, in the case where the modulation power signal S is contained in the input power P, the measuring device 1 determines the control command C based on the modulation power signal S taken out from the input power P, and performs control such as switching (selecting) of the sensor (target sensor 7t) to be supplied with power, starting or stopping of the supply of power to the target sensor 7t, or the like.

As a result, the control commands C for the activation or stopping of the desired sensor 7, the switching of the sensor 7 used when a plurality of the sensors 7 are present, and the like which are carried out from a stationary side or the like, remote from the subject to be measured 9, may be received and executed without additionally including a reception circuit and the like needed for wireless communication. Thus, it is possible to reduce the power consumption of the measuring device 1, reduce the size of the measuring device 1, and the like.

(2) In some embodiments, in the configuration of (1), the modulation power signal S is a signal corresponding to any of a selection command to select at least one of the at least one sensor 7 as the target sensor 7t to be supplied with the power, and a start or stop command to start or stop the supply of power to the target sensor 7t.

According to the configuration of (2), the control command C, such as selecting or switching the sensor 7, starting or stopping the measurement, and the like can be processed.

(3) In some embodiments, in the configuration of (2), a plurality of the sensors 7 are connected to the measuring device 1; there is further provided a selector 4 connected to each of the plurality of sensors 7 and the power source unit 2, and configured to be able to bring the target sensor 7t and the power source unit 2 into a connection status and to bring the other sensors 7 excluding the target sensor 7 and the power source unit 2 into a non-connection status; and the controller 3 controls the selector 4 to cause the target sensor 7t specified based on the selection command and the power source unit 2 to be in the connection status.

According to the configuration of (3), the measuring device 1 is configured to be able to switch the sensor 7 to be supplied with power by controlling the selector 4 by the control command C. Specifically, the switching is performed such that the power is supplied to the sensor 7 specified by the selection command but is not supplied to the other sensors 7 excluding the specified sensor 7. This facilitates the measurement being limited to the target sensor 7t, thereby making it possible to achieve power savings.

Further, for example, testing (verification) of vibration characteristics may be performed by using the sensor 7 (for example, a strain gauge) installed on a rotor blade of a turbine, but the opportunity to perform the testing thereof is limited. At this time, since a centrifugal force acts on the sensor 7 installed on a high-speed rotating body of the turbine or the like, the installed sensor 7 may be damaged during the testing. However, in a case where the sensor 7 is damaged, it is possible to continue the measurement without interruption by switching to another normal sensor 7, thereby making it possible to reliably obtain effective measurement data necessary for the testing (verification) at a precious testing opportunity.

(4) In some embodiments, in the configurations of (1) to (3), the modulation power signal S is formed by a pulsed voltage superimposed on a DC voltage to serve as the power-source power Pa.

According to the configuration of (4), the superimposing of the modulation power signal S on the power-source power Pa, the separation of the modulation power signal S, and the like may be easily performed.

(5) In some embodiments, in the configurations of (1) to (4), there is further provided a wireless transmission unit 52 configured to wirelessly transmit a detection result obtained by the sensor (7).

According to the configuration of (5), the measuring device 1 is configured to be able to transmit the detection result of the target sensor 7t to the outside by wireless. This makes it possible to easily obtain a measurement value at a remote location. Further, as described above, the measurement device 1 can receive the control command C by the modulation power signal S, and thus it is possible to omit a reception circuit or the like for wireless communication in the measuring device 1, thereby making it possible to reduce in power consumption and reduce in size of the measuring device 1 by omitting the reception circuit while including the wireless transmission unit 52 (transmission circuit).

(6) A measuring system 6 according to at least one embodiment of the disclosure includes: the measuring device 1 according to any one of the configurations of (1) to (5); at least one sensor 7 connected to the measuring device 1; and an outside power source 8, which is a power supplying source of power-source power Pa needed for operation of the measuring device 1, and is able to supply input power P, in which a modulation power signal S is superimposed on the power-source power Pa, to the measuring device 1.

According to the configuration of (6), the measuring system 6 includes the measuring device 1 described above, at least one sensor 7 connected to the measuring device 1, and the outside power source 8 configured to supply the power-source power Pa of the measuring device 1 and the modulation power signal S. This configuration exhibits the same effects as those of the configurations of (1) to (5).

(7) In some embodiments, in the configuration of (6), the outside power source 8 is a wireless power supply device configured to wirelessly supply power to the measuring device 1, and the stated wireless power supply device includes a light source 82, a solar battery 83 capable of generating an electromotive force in accordance with irradiation light W emitted from the light source 82, and a modulation unit 84 configured to modulate the irradiation light W emitted to the solar battery 83 in accordance with a control command C communicated to the measuring device 1.

According to the configuration of (7), the outside power source 8 of the measuring device 1 is a wireless power supply device configured to perform optical wireless power supply, and the control command C for the measuring device 1 is communicated to the measuring device 1 by modulating the irradiation light W emitted from the light source 82 to the solar battery 83 in accordance with the control command C. The electromotive force generated by the solar battery 83 varies depending on the amount of light of the irradiation light W or the like, but the modulation power signal S can be easily superimposed on the electromotive force for enabling the measuring device 1 to operate by modulating the irradiation light W from the light source 82. Further, in comparison with a case where a battery or the like is built in each of the sensors 7, the measuring device 1, or the like, it is possible to eliminate the need for replacing the battery, thereby making it possible to improve the efficiency of the measurement.

(8) In some embodiments, in the configuration of (7), the solar battery 83 is installed along a circumferential direction on a rotary shaft 91 of a rotating body which is a subject to be measured 9, the measuring device 1 is installed on the rotary shaft (91), and the light source 82 is installed to emit the irradiation light W toward a position in an axial direction of the rotary shaft (91), on which the solar battery 83 is installed.

According to the configuration of (8), the solar battery 83 is disposed along the circumferential direction on the rotating shaft 91 of a turbine, for example, to circle the rotary shaft 91, and the irradiation light W is emitted from the light source 82 toward the solar battery 83 on the rotary shaft 91. This makes it possible to supply (apply), to the measuring device 1, a power-source voltage in accordance with the amount of light of the irradiation light W of the light source 82.

(9) In some embodiments, in the configuration of (8), the at least one sensor 7 is a strain gauge, and is installed on a rotary blade included in the rotating body.

According to the configuration of (9), strain, vibration, and the like of a rotary blade of a rotating body such as a rotor blade of a turbine at the time of rotation, may be appropriately measured by the measuring device 1.

(10) In some embodiments, in the configuration of (6), the outside power source 8 is a wireless power supply device configured to wirelessly supply power to the measuring device 1; the stated wireless power supply device includes an AC power source 82w, a power transmission circuit section 85s configured to wirelessly transmit AC power outputted form the AC power source 82w, a power reception circuit section 85r configured to receive the AC power transmitted wirelessly, and a modulation unit 84 configured to modulate the AC power to be wirelessly transmitted to the power reception circuit section 85r in accordance with a control command C to be communicated to the controller 3 of the measuring device 1; and the measuring device 1 includes a separator section 86 configured to separate a modulation component of the AC power to be wirelessly transmitted to the power reception circuit section 85r, and also includes a detection unit 22 configured to detect the modulation power signal S by using the separator section 86.

According to the configuration of (10), the outside power source 8 of the measuring device 1 is a wireless power supply device of a magnetic field coupling scheme (such as an electromagnetic induction scheme) using a magnetic field (magnetic flux) as a transmission medium, or an electromagnetic wave scheme using electromagnetic waves such as microwaves as a transmission medium, for example; and the control command C for the measuring device 1 is communicated to the measuring device 1 by modulating the medium such as a magnetic field or electromagnetic waves for performing wireless transmission in accordance with the control command C. With this, the modulation power signal S can be easily superimposed on the power-source power Pa for enabling the measuring device 1 to operate. Further, in a case where a battery or the like is built in each of the sensors 7, the measuring device 1, or the like, it is possible to eliminate the need for replacing the battery, thereby making it possible to improve the efficiency of the measurement.

(11) A measuring method according to at least one embodiment of the disclosure is a measuring method for performing measurement by at least one sensor 7, the method including: a step of acquiring input power P, in which a modulation power signal S is superimposed on power-source power Pa, from an outside power source 8 as a power supplying source; and a step of controlling the presence or absence of supply of power to the at least one sensor 7 based on the modulation power signal S.

According to the configuration of (11), effects similar to those of the configuration of (1) are exhibited.

While preferred embodiments of the invention have been described as above, it is to be understood that variations and modifications will be apparent to those skilled in the art without departing from the scope and spirits of the invention. The scope of the invention, therefore, is to be determined solely by the following claims.

1. A measuring device connected to at least one sensor, the measuring device comprising:
a power source unit connected to an outside power source as a power supplying source, and configured to be supplied with input power, from the outside power source, in which a modulation power signal is superimposed on power-source power for the measuring device; and
a controller configured to control presence or absence of supply of power to the at least one sensor based on the modulation power signal.

2. The measuring device according to claim 1,
wherein the modulation power signal is a signal corresponding to any of a selection command to select at least one of the at least one sensor as a target sensor to be supplied with power, and a start or stop command to start or stop the supply of power to the target sensor.

3. The measuring device according to claim 2,
wherein a plurality of the sensors are connected to the measuring device,
the measuring device further includes a selector connected to each of the plurality of sensors and the power source unit, and configured to be able to bring the target sensor and the power source unit into a connection status and to bring the other sensors excluding the target sensor and the power source unit into a non-connection status, and
the controller controls the selector to cause the target sensor specified based on the selection command and the power source unit to be in the connection status.

4. The measuring device according to claim 1,
wherein the modulation power signal is formed by a pulsed voltage superimposed on a DC voltage to serve as the power-source power.

5. The measuring device according to claim 1, further comprising:
a wireless transmission unit configured to wirelessly transmit a detection result obtained by the sensor.

6. A measuring system comprising:
the measuring device according to claim 1;
at least one sensor connected to the measuring device; and
an outside power source, which is a power supplying source of power-source power needed for operation of the measuring device, and is able to supply input power, in which a modulation power signal is superimposed on the power-source power, to the measuring device.

7. The measuring system according to claim 6,
wherein the outside power source is a wireless power supply device configured to wirelessly supply power to the measuring device, and
the wireless power supply device includes,
a light source,
a solar battery capable of generating an electromotive force in accordance with irradiation light emitted from the light source, and
a modulation unit configured to modulate the irradiation light emitted to the solar battery in accordance with a control command communicated to the measuring device.

8. The measuring system according to claim 7,
wherein the solar battery is installed along a circumferential direction on a rotary shaft of a rotating body to serve as a subject to be measured,
the measuring device is installed on the rotary shaft, and
the light source is installed to emit the irradiation light toward a position in an axial direction of the rotary shaft on which the solar battery is installed.

9. The measuring system according to claim 8,
wherein the at least one sensor is a strain gauge, and is installed on a rotary blade included in the rotating body.

10. The measuring system according to claim 6,
wherein the outside power source is a wireless power supply device configured to wirelessly supply power to the measuring device,
the wireless power supply device includes,
an AC power source,
a power transmission circuit section configured to wirelessly transmit AC power outputted from the AC power source,
a power reception circuit section configured to receive the AC power transmitted wirelessly, and
a modulation unit configured to modulate the AC power to be wirelessly transmitted to the power reception circuit section in accordance with a control command to be communicated to the controller of the measuring device, and
the measuring device includes a separator section configured to separate a modulation component of the AC power to be wirelessly transmitted to the power reception circuit section, and also includes a detection unit configured to detect the modulation power signal by using the separator section.

11. A measuring method for performing measurement by at least one sensor, the method comprising:
acquiring input power in which a modulation power signal is superimposed on power-source power, from an outside power source as a power supplying source; and
controlling presence or absence of supply of power to the at least one sensor based on the modulation power signal.
